(19) United States
(12) Patent Application Publication
(10) Pub. No.: US 2010/0307580 A1
(43) Pub. Date: Dec. 9, 2010

(54) Lateral Organic Optoelectronic Devices And Applications Thereof

(76) Inventors: David Loren Carroll, Winston-salem, NC (US); Jiwen Liu, Winston-salem, NC (US); Manoj A.G. Namboothiry, Winston-salem, NC (US)

Correspondence Address: KILPATRICK STOCKTON LLP, 1001 WEST FOURTH STREET, WINSTON-SALEM, NC, 27101, US

(21) Appl. No.: 12/740,168

(22) PCT Filed: Nov. 3, 2008
(86) PCT No.: PCT/US2008/082262

§ 371 Date: Apr. 28, 2010

Related U.S. Application Data
(60) Provisional application No. 61/001,700, filed on Nov. 1, 2007.

(51) Int. Cl. H01L 31/0232; H01L 31/18

(52) U.S. Cl. 136/256; 438/69; 257/E31.127; 257/E31.032

(57) ABSTRACT

The present invention provides organic optoelectronic devices including organic photovoltaic devices. In some embodiments of the present invention, organic optoelectronic devices are operable to convert electromagnetic energy received at one or more points at the side or circumferential area of an optical fiber core into electrical energy.

### RELATED APPLICATION DATA

The present application hereby claims priority under 35 U.S.C. §119(e) to U.S. Provisional Patent Application Ser. No. 61/001,700 filed Nov. 1, 2007, which is hereby incorporated by reference in its entirety.

### STATEMENT OF GOVERNMENT LICENSE RIGHTS

This invention was made through the support of the Department of Defense—United States Air Force Office of Scientific Research (AFOSR) Grant No. FA9550-04-1-0161. The Federal Government retains certain license rights in this invention.

### FIELD OF THE INVENTION

The present invention relates to organic optoelectronic devices and, in particular, to organic photovoltaic devices.

### BACKGROUND OF THE INVENTION

Optoelectronic devices using organic materials are becoming increasingly desirable in a wide variety of applications for a number of reasons. Materials used to construct organic optoelectronic devices are relatively inexpensive in comparison to their inorganic counterparts thereby providing cost advantages over optoelectronic devices produced with inorganic materials. Moreover, organic materials provide desirable physical properties, such as flexibility, permitting their use in applications unsuitable for rigid materials. Examples of organic optoelectronic devices comprise organic photovoltaic cells, organic light emitting devices (OLEDs), and organic photodetectors.

Photovoltaic devices convert electromagnetic radiation into electricity by producing a photo-generated current when connected across a load and exposed to light. The electrical power generated by photovoltaic cells can be used in many applications including lighting, heating, battery charging, and powering devices requiring electrical energy.

When irradiated under an infinite load, a photovoltaic device produces its maximum possible voltage, the open circuit voltage or V_{oc}. When irradiated with its electrical contacts shorted, a photovoltaic device produces its maximum current, I short circuit or I_{sc}. Under operating conditions, a photovoltaic device is connected to a finite load, and the electrical power output is equal to the product of the current and voltage. The maximum power generated by a photovoltaic device cannot exceed the product of V_{oc} and I_{sc}. When the load value is optimized for maximum power generation, the current and voltage have the values Iₘₐₓ and Vₘₐₓ respectively.

A key characteristic in evaluating a photovoltaic cell's performance is the fill factor, ff. The fill factor is the ratio of the photovoltaic cell's actual power to its power if both current and voltage were at their maxima. The fill factor of a photovoltaic cell is provided according to equation (1).

ff=(IₘₐₓVₘₐₓ)/I_{sc}V_{oc}) (1)

The fill factor of a photovoltaic is always less than 1, as I_{sc} and V_{oc} are never obtained simultaneously under operating conditions. Nevertheless, as the fill factor approaches a value of 1, a device demonstrates less internal resistance and, therefore, delivers a greater percentage of electrical power to the load under optimal conditions.

Photovoltaic devices may additionally be characterized by their efficiency of converting electromagnetic energy into electrical energy. The conversion efficiency, ηₚ, of a photovoltaic device is provided according to equation (2) where P_{inc} is the power of the light incident on the photovoltaic.

η=ff*(I_{sc}V_{oc})P_{inc} (2)

Devices utilizing crystalline or amorphous silicon dominate commercial applications, and some have achieved efficiencies of 23% or greater. However, efficient crystalline-based devices, especially of large surface area, are difficult and expensive to produce due to the problems in fabricating large crystals free from crystalline defects that promote exciton recombination. Commercially available amorphous silicon photovoltaic cells demonstrate efficiencies ranging from about 4 to 12%.

Constructing organic photovoltaic devices having efficiencies comparable to inorganic devices poses a technical challenge. Some organic photovoltaic devices demonstrate efficiencies on the order of 1% or less. The low efficiencies displayed in organic photovoltaic devices results from a severe length scale mismatch between exciton diffusion length (L_{D}) and organic layer thickness. In order to have efficient absorption of visible electromagnetic radiation, an organic film must have a thickness of about 500 nm. This thickness greatly exceeds exciton diffusion length which is typically about 50 nm, often resulting in exciton recombination.

It would be desirable to provide organic photovoltaic devices which display increased efficiencies in converting electromagnetic energy into electrical energy. In view of the advantages of organic optoelectronic devices discussed herein, it would be desirable to provide organic photovoltaic devices that provide efficiencies comparable to and, in some cases, greater than inorganic photovoltaic devices.

### SUMMARY

The present invention provides organic optoelectronic devices, including organic photovoltaic devices, having a fiber structure and methods of making the same.

In one embodiment, the present invention provides an optoelectronic device comprising a fiber core, a radiation transmissive first electrode surrounding the fiber core, at least one photosensitive organic layer surrounding the first electrode and electrically connected to the first electrode, and a non-radiation transmissive second electrode partially covering the organic layer and electrically connected to the organic layer. In partially covering the organic layer, in some embodiments, the non-radiation transmissive second electrode does not completely cover the organic layer.

In some embodiments, the non-radiation transmissive second electrode covers less than about 95% of the photosensitive organic layer. In other embodiments, the non-radiation transmissive second electrode covers less than about 90%, less than about 80%, or less than about 70% of the photosensitive organic layer. In another embodiment, the non-radiation transmissive second electrode covers less than about 60% of the photosensitive organic layer. In a further embodiment the non-radiation transmissive second electrode covers less than about 50% of the photosensitive organic layer. In some embodiments, the non-radiation transmissive second electrode covers less than about 30% or less than about 20% of the photosensitive organic layer. In some embodiments, the non-radiation transmissive second electrode covers less than about 10% of the photosensitive organic layer.

In some embodiments, an optoelectronic device of the present invention comprises a photovoltaic cell.

In some embodiments, the fiber core of the optoelectronic device is bent at an angle to form a V-shaped structure. In one embodiment, for example, the fiber core of the optoelectronic device is bent at an angle of 90 degrees. In another embodiment, the fiber core of the optoelectronic device is bent at an angle of less than about 90 degrees. In a further embodiment, the fiber core of the optoelectronic device is bent at an angle greater than about 90 degrees.

In another embodiment, the present invention provides an optoelectronic device comprising at least one pixel comprising at least one photovoltaic cell, the photovoltaic cell comprising a fiber core, a radiation transmissive first electrode surrounding the fiber core, at least one photosensitive organic layer surrounding the first electrode and electrically connected to the first electrode, and a second electrode partially covering the organic layer and electrically connected to the organic layer. In some embodiments, a pixel comprises a plurality of photovoltaic cells. In other embodiments, an optoelectronic device comprises an array of pixels. In a further embodiment, an optoelectronic device comprises an array of pixels, each pixel comprising a plurality of photovoltaic cells.

In another aspect, the present invention provides methods of making optoelectronic devices. A method for producing an optoelectronic device, according to an embodiment of the present invention, comprises providing a fiber core, disposing a radiation transmissive first electrode on a surface of the core, disposing at least one photosensitive organic layer in electrical communication with the first electrode, and disposing a non-radiation transmissive second electrode in electrical communication with the organic layer, wherein the non-radiation transmissive second electrode partially covers the photosensitive organic layer. In some embodiments, the optoelectronic device comprises a photovoltaic cell.

The present invention additionally provides methods of converting electromagnetic energy into electrical energy. In one embodiment, a method of the present invention utilizes wave-guiding to increase the efficiency of conversion of electromagnetic energy into electrical energy. Embodiments of optoelectronic devices of the present invention described herein may utilize wave-guiding to increase such efficiency.

In some embodiments, a method for converting electromagnetic energy into electrical energy comprises receiving radiation at a side or circumferential area of an optoelectronic device, the optoelectronic device comprising a fiber core, a radiation transmissive first electrode surrounding the fiber core, at least one photosensitive organic layer surrounding the first electrode and electrically connected to the first electrode, and a non-radiation transmissive second electrode partially covering the organic layer and electrically connected to the organic layer. Once the radiation is received at one or more points along the side of the optoelectronic device, as opposed to being received at an end of the device for transmission down the longitudinal axis of the fiber core, the radiation is transmitted into the at least one photosensitive organic layer to generate excitons in the organic layer. The generated excitons are subsequently separated into holes and electrons and the electrons removed into an external circuit in communication with the optoelectronic device.

In some embodiments, radiation is incident on a side of the optoelectronic device at any desired angle. In one embodiment, radiation is received by the optoelectronic device in a plane normal to the longitudinal axis of the fiber core. In some embodiments, the fiber structure of an optoelectronic device permits incident radiation to be received and collected over a broad range of angles. In some embodiments, an optoelectronic device of the present invention can receive and/or collect radiation having an angle incident to the side or circumferential area of the optoelectronic device ranging from about 0 degrees to about 180 degrees. In another embodiment, an optoelectronic device can receive and/or collect radiation have an angle of incidence ranging from about 0 degrees to about 90 degrees.

In being operable to receive incident radiation over a wide range of angles, optoelectronic devices of the present invention, in some embodiments, are not limited to any particular orientation to maximize the receipt and/or capture of radiation. As a result, optoelectronic devices of the present invention can be considered to have a radiation collector or concentrator integral therewith.

Embodiments of methods of converting electromagnetic energy into electrical energy additionally contemplate modulating the angle of incidence of radiation at the side of the optoelectronic device. In some embodiments, modulating the angle of incidence comprises changing the orientation or position of the optoelectronic device relative to the source of the incident radiation. In other embodiments, modulating the angle of incidence comprises changing position of the light source providing the radiation relative to the position of the optoelectronic device.

These and other embodiments are of the present invention are described in greater detail in the detailed description of the invention which follows.

### BRIEF DESCRIPTION OF THE FIGURES

FIG. 1 illustrates a cross-section of an optoelectronic device according to one embodiment of the present invention.

FIG. 2 illustrates an optoelectronic device according to one embodiment of the present invention.

FIG. 3 displays short circuit currents for an optoelectronic device according to an embodiment of the present invention.

FIG. 4 displays open circuit voltages for an optoelectronic device according to an embodiment of the present invention.

FIG. 5 displays short circuit currents for an optoelectronic device according to an embodiment of the present invention.

FIG. 6 displays open circuit voltages for an optoelectronic device according to an embodiment of the present invention.

### DETAILED DESCRIPTION

The present invention provides organic optoelectronic devices, including organic photovoltaic devices, having a fiber structure. In one embodiment, the present invention provides an optoelectronic device comprising a fiber core, a radiation transmissive first electrode surrounding the fiber core, at least one photosensitive organic layer surrounding the first electrode and electrically connected to the first electrode, and a non-radiation transmissive second electrode partially covering the organic layer and electrically connected to the organic layer. In some embodiments, the optoelectronic device comprises a photovoltaic cell.

In some embodiments, the non-radiation transmissive second electrode covers less than about 95% of the photosensitive organic layer. In other embodiments, the non-radiation transmissive second electrode covers less than about 90%, less than about 80%, or less than about 70% of the photosensitive organic layer. In another embodiment, the non-radiation transmissive second electrode covers less than about 60% of the photosensitive organic layer. In a further embodiment the non-radiation transmissive second electrode covers less than about 50% of the photosensitive organic layer. In some embodiments, the non-radiation transmissive second electrode covers less than about 30% or less than about 20% of the photosensitive organic layer. In some embodiments, the non-radiation transmissive second electrode covers less than about 10% of the photosensitive organic layer.

Turning now to components that can be included in various embodiments of optoelectronic devices of the present invention, optoelectronic devices of the present invention comprise a fiber core. The fiber core, according to embodiments of the present invention, comprises an optical fiber. Optical fibers suitable for use in the present invention can comprise glass optical fibers, quartz optical fibers, and plastic optical fibers (POF). Plastic optical fibers, in some embodiments, can be constructed of polymethyl methacrylate. In other embodiments, plastic optical fibers can be constructed of perfluorocyclobutane (PFBC) containing polymers, such as perfluorocyclobutane poly(arylether)s. Optical fibers, according to some embodiments of the present invention, can comprise single mode optical fibers and multi-mode optical fibers. Optical fibers for use in the present invention can be flexible.

In some embodiments, the fiber core comprises an indium tin oxide (ITO) fiber. When the optical fiber core comprises an ITO fiber, a separate and distinct first electrode may be optional. The ITO fiber, in some embodiments, serves as both the fiber core and first electrode. In other embodiments, a first electrode comprising a radiation transmissive conducting oxide is disposed on the surface of the ITO fiber as provided herein.

In some embodiments, a fiber core of an optoelectronic device of the present invention can have a diameter ranging from about 1 μm to about 2 mm. In other embodiments, a fiber core can have a diameter ranging from about 90 μm to about 1 mm. In a further embodiment, a fiber core can have a diameter ranging from about 20 μm to about 800 μm.

A fiber core, according to some embodiments, can have any desired length. In some embodiments a fiber core can have a length ranging from about 500 nm to about 100 mm. In other embodiments, a fiber core can have a length ranging from about 1 μm to about 1 mm. In a further embodiment, a fiber core can have a length ranging from about 10 μm to about 100 μm.

Fiber cores, according to some embodiments of the present invention, can further comprise one or more upconverters. As understood by one of skill in the art, an upconverter is a material operable to emit electromagnetic radiation having energy greater than that of the electromagnetic radiation absorbed by the material to create the excited state. Upconverters suitable for use in the present invention, in some embodiments, can absorb infrared radiation and emit visible radiation at wavelengths operable to be absorbed by photosensitive organic layers of optoelectronic devices of the present invention.

Upconverters, in some embodiments, can include materials comprising at least one Lanthanide series element. In some embodiments, upconverter materials can comprise nanoparticles comprising at least one Lanthanide series element. Lanthanide series elements suitable for use in upconverter materials according to some embodiments of the present invention comprise erbium, ytterbium, dysprosium, holmium, or mixtures thereof. In some embodiments, upconverter materials comprise metal oxides and metal sulfides doped with ions of erbium, ytterbium, dysprosium, holmium, or mixtures thereof. In other embodiments, optical fibers may be doped directly with ions of erbium, ytterbium, dysprosium, holmium, or mixtures thereof.

In other embodiments, upconverter materials can comprise organic chemical species. Organic upconverter materials can comprise H₂C₆N and 4-dialkylamino-1,8-naphthalimides as well as 1,8-naphthalimide derivatives and compounds, such as multibranched naphthalimide derivatives TPA-NA1, TPA-NA2, and TPA-NA3. Organic upconverter materials can also comprise 4-(dimethylamino)cinnamonitrile (cis and trans), trans-4-[4-(dimethylamino)styryl]-1-methylpyridinium iodide, 4-[4-(dimethylamino)styryl]pyridine, 4-(diethylamino)benzaldehyde diphenylhydrazone, trans-4-[4-(dimethylamino)styryl]-1-methylpyridinium p-toluenesulfonate, 2-[ethyl[4-[2-(4-nitrophenyl)ethenyl]phenyl]amino]ethanol, 4-dimethylamino-4′-nitrostilbene, Disperse Orange 25, Disperse Orange 3, and Disperse Red 1.

In some embodiments, upconverter materials comprise an anti-Stokes material, laser dye, anti-counterfeiting dye or combination thereof. Anti-Stokes materials, laser dyes and anti-counterfeiting dyes, in some embodiments, comprise substituted benzophenones, biphenyls, diphenyls, infrared dyes such as polymethines, and spectral sensitizers such as cyanines merocyanines. In some embodiments, anti-counterfeiting dyes comprise phosphors, fluorophors, thermochromic, and/or photochromic chemical species.

In a further embodiment, upconverter materials can comprise quantum dots. Quantum dots, according to some embodiments, can comprise III/V and II/VI semiconductor materials, such as cadmium selenide (CdSe), cadmium telluride (CdTe), and zinc selenide (ZnSe). Upconverter materials can also comprise core-shell architectures of quantum dots.

In addition to those provided herein, embodiments of the present invention contemplate additional upconverter materials comprising transition metals, such as chromium.

In another embodiment, fiber cores, according to some embodiments of the present invention, can further comprise one or more downconverters. As understood by one of skill in the art, a downconverter is a material operable to emit electromagnetic radiation having energy less than that of the electromagnetic radiation absorbed by the material to create the excited state. In some embodiments, downcoverters comprise quantum dots, including lead sulfide and lead selenide quantum dots.

Upconverters and/or downcoverters, in some embodiments, can be disposed within the optical fiber core. In other embodiments, upconverters and/or downconverters can be disposed on a surface of the optical fiber core and at the interface of the fiber core with a radiation transmissive first electrode.

Fiber cores, in some embodiments, can further comprise at least one scattering agent. In another embodiment, a fiber core can comprise a plurality of scattering agents. Scattering agents, according to embodiments of the present invention, can scatter electromagnetic radiation received in a plane normal to the longitudinal axis of the fiber core. In some embodiments, scattering agents can scatter the electromagnetic radiation radially outward from the fiber core permitting absorption of the scattered radiation by one or more photosensitive organic layers surrounding the fiber core.

Scattering agents, in some embodiments, can comprise transition metal nanoparticles. Transition metals suitable for use as scattering agents, in an embodiment, can comprise gold, silver, copper, niobium, palladium, and platinum. Transition metal nanoparticles, according to some embodiments, can comprise rods or wires. In one embodiment, for example, a transition metal nanorod or nanowire can have a diameter ranging from about 2 nm to about 50 nm.

Optoelectronic devices of the present invention comprise a radiation transmissive first electrode surrounding the fiber core. Radiation transmissive, as used herein, refers to the ability to at least partially pass radiation in the visible region of the electromagnetic spectrum. In some embodiments, radiation transmissive materials can pass visible electromagnetic radiation with minimal absorbance or other interference. Moreover, electrodes, as used herein, refer to layers that provide a medium for delivering photo-generated current to an external circuit or providing bias voltage to the optoelectronic device. An electrode provides the interface between the photoactive regions of an organic optoelectronic device and a wire, lead, trace, or other means for transporting the charge carriers to or from the external circuit.

A radiation transmissive first electrode, according to some embodiments of the present invention, comprises a radiation transmissive conducting oxide. Radiation transmissive conducting oxides, in some embodiments, can comprise indium tin oxide (ITO), gallium indium tin oxide (GITO), antimony tin oxide (ATO), indium antimony oxide (IAO), and zinc indium tin oxide (ZITO). In another embodiment, the radiation transmissive first electrode can comprise a radiation transmissive polymeric material such as polyanaline (PAM) and its chemical relatives.

In some embodiments, 3,4-polyethylenedioxythiophene (PEDOT) can be a suitable radiation transmissive polymeric material for the first electrode. In other embodiments, a radiation transmissive first electrode can comprise a carbon nanotube layer having a thickness operable to at least partially pass visible electromagnetic radiation.

In another embodiment, a radiation transmissive first electrode can comprise a composite material comprising a nanoparticle phase dispersed in a polymeric phase. The nanoparticle phase, in one embodiment, can comprise carbon nanotubes, fullerenes, or mixtures thereof. In a further embodiment, a radiation transmissive first electrode can comprise a metal layer having a thickness operable to at least partially pass visible electromagnetic radiation. In some embodiments, a metal layer can comprise elementally pure metals or alloys. Metals suitable for use as a radiation transmissive first electrode can comprise high work function metals. In one embodiment, for example, a high work function metal has a work function of at least 4.7 eV.

In some embodiments, a radiation transmissive first electrode can have a thickness ranging from about 10 nm to about 1 μm. In other embodiments, a radiation transmissive first electrode can have a thickness ranging from about 100 nm to about 900 nm. In another embodiment, a radiation transmissive first electrode can have a thickness ranging from about 200 nm to about 800 nm. In a further embodiment, a radiation transmissive first electrode can have a thickness greater than 1 μm.

Optoelectronic devices of the present invention comprise at least one photosensitive organic layer. Optoelectronic devices, according to some embodiments, can comprise a plurality of photosensitive organic layers.

In some embodiments, a photosensitive organic layer has a thickness ranging from about 30 nm to about 1 μm. In other embodiments, a photosensitive organic layer has a thickness ranging from about 80 nm to about 800 nm. In a further embodiment, a photosensitive organic layer has a thickness ranging from about 100 nm to about 300 nm.

A photosensitive organic layer, according to embodiments of the present invention, comprises at least one photoactive region in which electromagnetic radiation is absorbed to produce excitons which may subsequently dissociate into electrons and holes. In some embodiments, a photoactive region can comprise a polymer. Polymers suitable for use in a photoactive region of a photosensitive organic layer, in one embodiment, can comprise conjugated polymers such as thiophenes including poly(3-hexylthiophene) (P3HT), poly(3-octylthiophene) (P30T), and polythiophene (PTh).

In some embodiments, polymers suitable for use in a photoactive region of a photosensitive organic layer can comprise semiconducting polymers. In one embodiment, semiconducting polymers include phenylene vinylenes, such as poly(phenylene vinylene) and poly(p-phenylene vinylene) (PPV), and derivatives thereof. In other embodiments, semiconducting polymers can comprise poly fluorenes, naphthalenes, and derivatives thereof. In a further embodiment, semiconducting polymers for use in a photoactive region of a photosensitive organic layer can comprise poly(2-vinylpyridine) (P2VP), polyamides, poly(N-vinylcarbazole) (PVCZ), polypyrrole (PPy), and polyaniline (PAn).

A photoactive region, according to some embodiments, can comprise small molecules. In one embodiment, small molecules suitable for use in a photoactive region of a photosensitive organic layer can comprise coumarin 6, coumarin 30, coumarin 102, coumarin 110, coumarin 153, and coumarin 480 D. In another embodiment, a small molecule can comprise merocyanine 540. In a further embodiment, small molecules can comprise 9,10-dihydrobenzo[a]pyrene-7(8H)-one, 7-methylbenzo[a]pyrene, pyrene, benzo[e]pyrene, 3,4-dihydroxy-3-cyclobutene-1,2-dione, and 1,3-bis[4-(dimethylamino)phenyl-2,4-dihydroxycyclobutenediylium dihydroxide.

In some embodiments of the present invention, exciton dissociation is precipitated at heterojunctions in the organic layer formed between adjacent donor and acceptor materials. Organic layers, in some embodiments of the present invention, comprise at least one bulk heterojunction formed between donor and acceptor materials. In other embodiments, organic layers comprise a plurality of bulk heterojunctions formed between donor and acceptor materials.

In the context of organic materials, the terms donor and acceptor refer to the relative positions of the highest occupied molecular orbital (HOMO) and lowest unoccupied molecular orbital (LUMO) energy levels of two contacting but different organic materials. This is in contrast to the use of these terms in the inorganic context, where donor and acceptor may refer to types of dopants that may be used to create inorganic n- and p-type layers, respectively. In the organic context, if the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

A photoactive region in a photosensitive organic layer, according to some embodiments of the present invention, comprises a polymeric composite material. The polymeric composite material, in an embodiment, can comprise a nanoparticle phase dispersed in a polymeric phase. Polymers suitable for producing the polymeric phase of a photoactive region can comprise conjugated polymers such as thiophenes including poly(3-hexylthiophene) (P3HT) and poly(3-octylthiophene) (P30T).

In some embodiments, the nanoparticle phase dispersed in the polymeric phase of a polymeric composite material comprises at least one carbon nanoparticle. Carbon nanoparticles can comprise fullerenes, carbon nanotubes, or mixtures thereof. Fullerenes suitable for use in the nanoparticle phase, in one embodiment, can comprise 1-(3-methoxycarbonyl)propyl-1-phenyl(6,6)C₆₁ (PCBM). Carbon nanotubes for use in the nanoparticle phase, according to some embodiments, can comprise single-walled nanotubes, multi-walled nanotubes, or mixtures thereof.

In some embodiments of the present invention, the polymer to nanoparticle ratio in polymeric composite materials ranges from about 1:4 to about 1:0.4. In other embodiments, the polymer to nanoparticle ratio in polymeric composite materials ranges from about 1:2 to about 1:0.6. In one embodiment, for example, the ratio of poly(3-hexylthiophene) to PCBM ranges from about 1:1 to about 1:0.4.

In a further embodiment, the nanoparticle phase dispersed in the polymeric phase comprises at least one nanowhisker. A nanowhisker, as used herein, refers to a crystalline carbon nanoparticle formed from a plurality of carbon nanoparticles. Nanowhiskers, in some embodiments, can be produced by annealing a photosensitive organic layer comprising the polymeric composite material. Carbon nanoparticles operable to form nanowhiskers, according to some embodiments, can comprise single-walled carbon nanotubes, multi-walled carbon nanotubes, and fullerenes. In one embodiment, nanowhiskers comprise crystalline PCBM. Annealing the photosensitive organic layer, in some embodiments, can further increase the dispersion of the nanoparticle phase in the polymeric phase.

In embodiments of photoactive regions comprising a polymeric phase and a nanoparticle phase, the polymeric phase serves as a donor material and the nanoparticle phase serves as the acceptor material thereby forming a heterojunction for the separation of excitons into holes and electrons. In embodiments wherein nanoparticles are dispersed throughout the polymeric phase, the photoactive region of the organic layer comprises a plurality of bulk heterojunctions.

In further embodiments, donor materials in a photoactive region of a photosensitive organic layer can comprise organometallic compounds including porphyrins, phthalocyanines, and derivatives thereof. Through the use of an organometallic material in the photoactive region, photosensitive devices incorporating such materials may efficiently utilize triplet excitons. It is believed that the singlet-triplet mixing may be so strong for organometallic compounds that the absorptions involve excitation from the singlet ground states directly to the triplet excited states, eliminating the losses associated with conversion from the singlet excited state to the triplet excited state. The longer lifetime and diffusion length of triplet excitons in comparison to singlet excitons may allow for the use of a thicker photoactive region, as the triplet excitons may diffuse a greater distance to reach the donor-acceptor heterojunction, without sacrificing device efficiency.

In further embodiments, acceptor materials in a photoactive region of a photosensitive organic layer can comprise perylenes, naphthalenes, and mixtures thereof.

In some embodiments, a photosensitive organic layer of an optoelectronic device further comprises one or more upconverter and/or downconverter materials. Photosensitive organic layers, in some embodiments, can comprise any of the upconverter and/or downconverter materials described herein.

Optoelectronic devices of the present invention comprise a non-radiation transmissive second electrode partially covering the photosensitive organic layer. In some embodiments, the non-radiation transmissive second electrode can comprise a metal. As used herein, metal refers to both materials composed of an elementally pure metal, e.g., gold, and also metal alloys comprising materials composed of two or more elementally pure materials. In some embodiments, the second electrode comprises gold, silver, aluminum, or copper. The second electrode, according to some embodiments, can have a thickness ranging from about 10 nm to about 10 μm. In other embodiments, the second electrode can have a thickness ranging from about 100 nm to about 1 μm. In a further embodiment, the second electrode can have a thickness ranging from about 200 nm to about 800 nm.

In partially covering the photosensitive organic layer, in some embodiments, the non-radiation transmissive second electrode does not completely cover the photosensitive organic layer. In some embodiments, the non-radiation transmissive second electrode covers less than about 95% of the photosensitive organic layer. In other embodiments, the non-radiation transmissive second electrode covers less than about 90%, less than about 80%, or less than about 70% of the photosensitive organic layer. In another embodiment, the non-radiation transmissive second electrode covers less than about 60% of the photosensitive organic layer. In a further embodiment the non-radiation transmissive second electrode covers less than about 50% of the photosensitive organic layer.

A layer comprising lithium fluoride (LiF), according to some embodiments, can be disposed between a photosensitive organic layer and second electrode. The LiF layer can have a thickness ranging from about 5 angstroms to about 10 angstroms.

In some embodiments, the LiF layer can be at least partially oxidized resulting in a layer comprising lithium oxide (Li₂O) and LiF. In other embodiments, the LiF layer can be completely oxidized resulting in a lithium oxide layer deficient or substantially deficient of LiF. In some embodiments, a LiF layer is oxidized by exposing the LiF layer to oxygen, water vapor, or combinations thereof. In one embodiment, for example, a LiF layer is oxidized to a lithium oxide layer by exposure to an atmosphere comprising water vapor and/or oxygen at a partial pressures of less than about 10⁻⁶ Torr. In another embodiment, a LiF layer is oxidized to a lithium oxide layer by exposure to an atmosphere comprising water vapor and/or oxygen at a partial pressures less than about 10⁻⁷ Torr or less than about 10⁻⁸ Torr.

In some embodiments, a LiF layer is exposed to an atmosphere comprising water vapor and/or oxygen for a time period ranging from about 1 hour to about 15 hours. In one embodiment, a LiF layer is exposed to an atmosphere comprising water vapor and/or oxygen for a time period greater than about 15 hours. In a further embodiment, a LiF layer is exposed to an atmosphere comprising water vapor and/or oxygen for a time period less than about one hour. The time period of exposure of the LiF layer to an atmosphere comprising water vapor and/or oxygen, according to some embodiments of the present invention, is dependent upon the partial pressures of the water vapor and/or oxygen in the atmosphere. The higher the partial pressure of the water vapor or oxygen, the shorter the exposure time.

Optoelectronic devices of the present invention, in some embodiments, can further comprise additional layers such as one or more exciton blocking layers. In embodiments of the present invention, an exciton blocking layer (EBL) can act to confine photogenerated excitons to the region near the dissociating interface and prevent parasitic exciton quenching at a photosensitive organic/electrode interface. In addition to limiting the path over which excitons may diffuse, an EBL can additionally act as a diffusion barrier to substances introduced during deposition of the electrodes. In some embodiments, an EBL can have a sufficient thickness to fill pin holes or shorting defects which could otherwise render an organic photovoltaic device inoperable.

An EBL, according to some embodiments of the present invention, can comprise a polymeric composite material. In one embodiment, an EBL comprises carbon nanoparticles dispersed in 3,4-polyethylenedioxythiophene:polystyrenesulfonate (PEDOT:PSS). In another embodiment, an EBL comprises carbon nanoparticles dispersed in poly(vinylidene chloride) and copolymers thereof. Carbon nanoparticles dispersed in the polymeric phases including PEDOT:PSS and poly(vinylidene chloride) can comprise single-walled nanotubes, multi-walled nanotubes, fullerenes, or mixtures thereof. In further embodiments, EBLs can comprise any polymer having a work function energy operable to permit the transport of holes while impeding the passage of electrons.

In some embodiments, an EBL may be disposed between the radiation transmissive first electrode and a photosensitive organic layer of an optoelectronic device. In some embodiments wherein the optoelectronic device comprises a plurality of photosensitive organic layers, EBLs can be disposed between the photosensitive organic layers.

Optoelectronic devices of the present invention, in some embodiments, can further comprise an external metallic contact. In one embodiment, the external metallic contact contacts the second electrode and is in electrical communication with the second electrode. The external metallic contact, in some embodiments, can be operable to extract current over at least a portion of the circumference and length of the fiber optoelectronic device. External metallic contacts, in some embodiments, can comprise metals including gold, silver, or copper. In a further embodiment, external metal contacts can be operable to reflect non-absorbed electromagnetic radiation back into at least one photosensitive organic layer for further absorption.

Optoelectronic devices, according to some embodiments of the present invention, can further comprise charge transfer layers. Charge transfer layers, as used herein, refer to layers which only deliver charge carriers from one section of an optoelectronic device to another section. In one embodiment, for example, a charge transfer layer can comprise an exciton blocking layer.

A charge transfer layer, in some embodiments, can be disposed between a photosensitive organic layer and radiation transmissive first electrode and/or a photosensitive organic layer and non-radiation transmissive second electrode. In other embodiments, charge transfer layers may be disposed between the non-radiation transmissive second electrode and protective layer of an optoelectronic device. Charge transfer layers, according to some embodiments, are not photoactive.

In some embodiments, layers of optoelectronic devices of the present invention can be etched to prevent or reduce frustrated total internal reflection. In one embodiment, an exciton blocking layer adjacent to a photosensitive organic layer can be etched on the side forming an interface with the organic layer. An exciton blocking layer comprising PEDOT, for example, can be etched on the side forming an interface with a P3HT/PCBM photosensitive organic layer.

In some embodiments, layers of an optoelectronic device can be etched by lithographic methods, including photolithographic methods. In one embodiment, a photolithographic resist is deposited onto the surface of the layer to be etched. Photolithographic resists, according to embodiments of the present invention, comprise positive resists or negative resists. Once the photolithographic resist is deposited, the resist is exposed to radiation and developed with appropriate solvent. A pattern remains on the layer of the photovoltaic device. Photolithographic resists can be laid down in any desired pattern. One pattern, for example, comprises a series of parallel lines spaced apart by a constant distance. After developing the resist, the layer of the optoelectronic device is then etched by any suitable polar organic solvent, such as acetone. The photolithographic resist is subsequently stripped from the layer of the optoelectronic device leaving behind an etched layer.

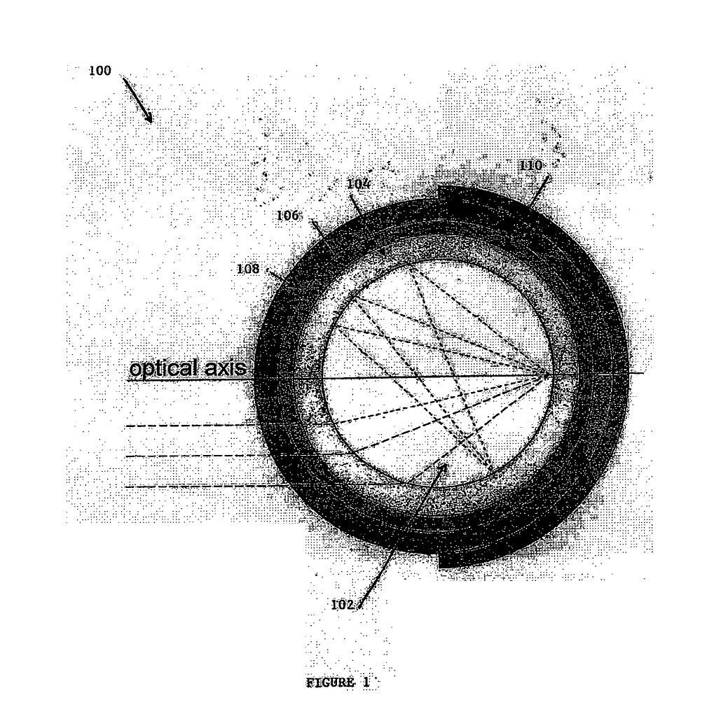

FIG. 1 illustrates a cross-section of an optoelectronic device according to one embodiment of the present invention. The optoelectronic device (100) illustrated in FIG. 1 comprises an optical fiber core (102). The optical fiber core (102) is surrounded by a radiation transmissive first electrode (104). The radiation transmissive first electrode (104) can comprise a radiation transmissive conducting oxide such as indium tin oxide, gallium indium tin oxide, or zinc indium tin oxide. The radiation transmissive first electrode (104) is surrounded by an exciton blocking layer (106). In some embodiments, the EBL (106) can comprise carbon nanoparticles dispersed in a polymeric phase such as 3,4-polyethylenedioxythiophene or poly(vinylidene chloride). The EBL (106) is surrounded by an photosensitive organic layer (108). The photosensitive organic layer (108), in some embodiments, comprises a P3HT-carbon nanoparticle polymeric composite. The photosensitive organic layer (108), in some embodiments, can be in direct electrical communication with the radiation transmissive first electrode (104). In other embodiments, a charge transfer layer, including an exciton blocking layer, may be disposed between the radiation transmissive first electrode (104) and the photosensitive organic layer (108) to provide indirect electrical communication between the radiation transmissive first electrode (104) and the photosensitive organic layer (108). The photosensitive organic layer (108). A non-radiation transmissive second electrode (110) partially covers the photosensitive organic layer (108). As illustrated, the portion of the photosensitive organic layer (108) and optoelectronic device (100) not covered by the non-radiation transmissive second electrode (110) is operable to receive electromagentic radiation for conversion into electrical energy. In the embodiment shown in FIG. 1, the non-radiation transmissive second electrode (110) covers about 50% of the photosensitive organic layer (108).

In some embodiments, the fiber core of the optoelectronic device is bent at an angle to form a V-shaped structure. In one embodiment, the fiber core of the optoelectronic device is bent at an angle of 90 degrees. In another embodiment, the fiber core of the optoelectronic device is bent at an angle of less than about 90 degrees. In a further embodiment, the fiber core of the optoelectronic device is bent at an angle greater than about 90 degrees.

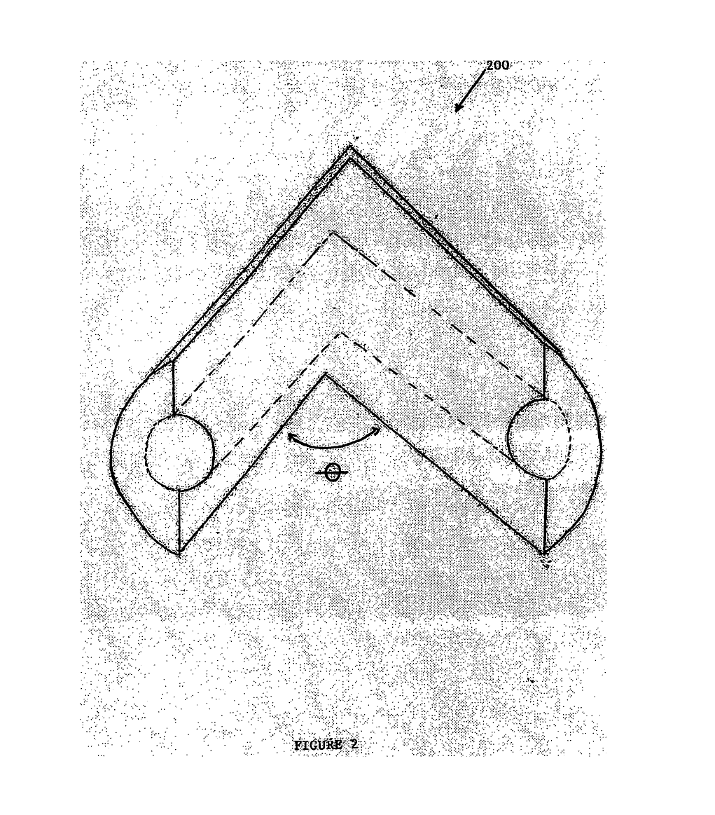

FIG. 2 illustrates an optoelectronic device according to one embodiment of the present invention wherein the fiber core of the optoelectronic device is bent. The optoelectronic device (200) illustrated in FIG. 2 has the same construction as the device presented in FIG. 1. However, the optoelectronic device in FIG. 1 is bent at an angle θ. In some embodiments, θ is about 90 degrees. In other embodiments, θ is greater than about 90 degrees. In a further embodiment θ is less than about 90 degrees. The bent structure of the optoelectronic device (200) shown in FIG. 2 permits radiation reflected from one side of the device to be captured by the opposing side, thereby increasing radiation absorption and conversion efficiency.

In some embodiments, one or a plurality optoelectronic devices of the present invention can be assembled into fabrics including woven fabrics and non-woven fabrics. In such embodiments, optoelectronic devices of the present invention can be incorporated into clothing, tents, backpacks and other articles and subsequently used for conversion of electromagnetic energy into electrical energy as provided herein.

In some embodiments, an optoelectronic device having a fiber structure comprises a photovoltaic cell. In one embodiment, a photovoltaic cell comprises a fiber core, a radiation transmissive first electrode surrounding the fiber core, at least one photosensitive organic layer surrounding the first electrode and electrically connected to the first electrode, and a non-radiation transmissive second electrode partially covering the organic layer and electrically connected to the organic layer.

Fiber photovoltaic cells, according to embodiments of the present invention, are operable to receive electromagnetic radiation in a plane normal to longitudinal axis of the optical fiber core. Electromagnetic radiation received in a plane normal to the longitudinal axis of the optical fiber core, in some embodiments, can be transmitted though the radiation transmissive first electrode and into the photosensitive organic layer through evanescence fields. In other embodiments, the received electromagnetic radiation can be scattered into the photosensitive organic layer by scattering agents within the optical fiber. In a further embodiment, at least a portion of the received electromagnetic radiation can undergo upconversion and be emitted into the photosensitive organic layer.

Fiber photovoltaic devices, according to some embodiments of the present invention, can display a fill factor greater than 0.2. In other embodiments, fiber photovoltaic devices can demonstrate a fill factor greater than 0.5. In a further embodiment, fiber photovoltaic devices can display a fill factor greater than 0.7.

In some embodiments, fiber photovoltaic devices of the present invention can display conversion efficiencies, ηₚ, greater than about 6%. Fiber photovoltaic devices, in other embodiments, can demonstrate conversion efficiencies greater than about 10%. In another embodiment, fiber photovoltaic devices can display conversion efficiencies greater than about 15%. In a further embodiment, fiber photovoltaic devices can display conversion efficiencies greater than 35%.

In some embodiments, the present invention provides an optoelectronic device comprising at least one pixel comprising at least one photovoltaic cell, the photovoltaic cell comprising a fiber core, a radiation transmissive first electrode surrounding the fiber core, at least one photosensitive organic layer surrounding the first electrode and electrically connected to the first electrode, and a non-radiation transmissive second electrode partially covering the organic layer and electrically connected to the organic layer. In some embodiments, a photovoltaic cell of a pixel comprises a plurality of photosensitive organic layers.

In some embodiments, a pixel comprises a plurality of photovoltaic cells. In other embodiments, an optoelectronic device comprises an array of pixels. In a further embodiment, an optoelectronic device comprises an array of pixels, each pixel comprising a plurality of photovoltaic cells.

Fiber photovoltaic cells for use in pixel applications, in some embodiments of the present invention, are constructed independently from one another. In such embodiments, component materials for one fiber photovoltaic cell are selected without reference to component materials selected for another fiber photovoltaic cell. In one embodiment, for example, one fiber photovoltaic cell can comprise a glass optical fiber core while another photovoltaic cell can comprise a plastic optical fiber core. As a result, in some embodiments, pixels and pixel arrays are not required to comprise fiber photovoltaic cells of identical construction. Fiber photovoltaic cell construction can be varied in any manner consistent with the materials and methods described herein to produce pixels and pixel arrays suitable for a wide range of applications.

In some embodiments, a plurality of fiber photovoltaic cells can be bundled. In such embodiments, each fiber photovoltaic cell can constitute a single pixel or the plurality of fiber photovoltaic cells can collectively constitute a single pixel.

In another aspect, the present invention provides methods of making optoelectronic devices. A method for producing an optoelectronic device, according to an embodiment of the present invention, comprises providing a fiber core, disposing a radiation transmissive first electrode on a surface of the core, disposing at least one photosensitive organic layer in electrical communication with the first electrode, and disposing a non-radiation transmissive second electrode in electrical communication with the organic layer, wherein the non-radiation transmissive second electrode partially covers the photosensitive organic layer. In some embodiments, the optoelectronic device comprises a photovoltaic cell.

Disposing a radiation transmissive first electrode on a fiber core, in some embodiments, comprises sputtering or dip coating a radiation transmissive conductive oxide onto a surface of the fiber core. In some embodiments, disposing a photosensitive organic layer in electrical communication with the first electrode comprises depositing the organic layer on the first electrode by dip coating, spin coating, vapor phase deposition, or vacuum thermal annealing. Disposing a second electrode in electrical communication with the photosensitive organic layer, according to some embodiments, comprises depositing the second electrode on the organic layer through vapor phase deposition, spin coating, or dip coating.

Methods of producing an optoelectronic device, in some embodiments, further comprise annealing the photosensitive organic layer or layers. In some embodiments where a photosensitive organic layer comprises a composite material comprising a polymer phase and a nanoparticle phase, annealing the organic layer can produce higher degrees of crystallinity in both the polymer and nanoparticle phases as well as result in greater dispersion of the nanoparticle phase in the polymer phase. Nanoparticle phases comprising fullerenes, single-walled carbon nanotubes, multi-walled carbon nanotubes, or mixtures thereof can form nanowhiskers in the polymeric phase as a result of annealing. Annealing a photosensitive organic layer, according to some embodiments, can comprise heating the organic layer at a temperature ranging from about 80° C. to about 155° C. for a time period of ranging from about 1 minute to about 30 minutes. In some embodiments, a photosensitive organic layer can be heated for about 5 minutes.

In some embodiments, a method for producing an optoelectronic device further comprises disposing at least one upconverter and/or scattering agent in the fiber core.

In addition to methods of producing optoelectronic devices, the present invention also provides methods for converting electromagnetic energy into electrical energy. Wave-guiding may be utilized to increase the efficiency of the conversion.

In one embodiment, a method for converting electromagnetic energy into electrical energy comprises receiving radiation at a side or circumferential area of an optoelectronic device, the optoelectronic device comprising a fiber core, a radiation transmissive first electrode surrounding the fiber core, at least one photosensitive organic layer surrounding the first electrode and electrically connected to the first electrode, and a non-radiation transmissive second electrode partially covering the organic layer and electrically connected to the organic layer. Once the radiation is received at one or more points along the side of the optoelectronic device, as opposed to being received at an end of the device for transmission along the longitudinal axis of the fiber core, the radiation is transmitted into the at least one photosensitive organic layer to generate excitons in the organic layer. The generated excitons are subsequently separated into holes and electrons at one or more heterojunctions in the organic layer and the electrons removed into an external circuit in communication with the optoelectronic device.

In some embodiments, transmitting electromagnetic radiation into a photosensitive organic layer comprises transmitting radiation through evanescence fields. In other embodiments, transmitting electromagnetic radiation into a photosensitive organic layer comprises upconverting at least a portion of the electromagnetic radiation received in a plane normal to longitudinal axis of the optical fiber. Upconverting, according to some embodiments of the present invention, comprises absorbing radiation received at a side of the optoelectronic device with an upconversion material to create an excited state and emitting radiation into at least one organic layer to relax the excited state, wherein the emitted radiation has a shorter wavelength than the absorbed radiation. In some embodiments, the portion of radiation absorbed by the upconversion material comprises infrared radiation.

In a further embodiment, transmitting the radiation received into the photosensitive organic layer comprises scattering the radiation into the organic layer with a scattering agent.

In some embodiments, a heterojunction comprises a plurality of bulk heterojunctions. As discussed herein, a bulk heterojunction is formed at the interface of a donor material and an acceptor material. In some embodiments, a donor material comprises a polymeric phase and the acceptor material comprises a nanoparticle phase. Donor and acceptor materials for use in methods of the present invention are consistent with those provided herein for optoelectronic devices.

In some embodiments, radiation is incident on a side of the optoelectronic device at any desired angle. In one embodiment, radiation is received by the optoelectronic device in a plane normal to the longitudinal axis of the fiber core. In some embodiments, the fiber structure of an optoelectronic device permits incident radiation to be received and collected over a broad range of angles. In some embodiments, an optoelectronic device of the present invention can receive and/or collect radiation having an angle incident to the side or circumferential area of the optoelectronic device ranging from about 0 degrees to about 180 degrees. In another embodiment, an optoelectronic device can receive and/or collect radiation have an angle of incidence ranging from about 0 degrees to about 90 degrees.

In being operable to receive incident radiation over a wide range of angles, optoelectronic devices of the present invention, in some embodiments, are not limited to any particular orientation to maximize the receipt and/or capture of radiation. As a result, optoelectronic devices of the present invention can be considered to have a radiation collector or concentrator integral therewith.

Embodiments of methods of converting electromagnetic energy into electrical energy additionally contemplate modulating the angle of incidence of radiation at the side of the optoelectronic device. In some embodiments, modulating the angle of incidence comprises changing the orientation or position of the optoelectronic device relative the source of the incident radiation, such as the sun. In other embodiments, modulating the angle of incidence comprises changing position of the light source providing the radiation relative to the position of the optoelectronic device.

In some embodiments of methods of the present invention, radiation received by an optoelectronic device of the present invention comprises visible radiation, ultraviolet radiation, infrared radiation or combinations thereof.

The present invention is now illustrated by the following non-limiting example.

### Example 1

### Lateral Organic Optoelectronic Device

A non-limiting example of a fiber optoelectronic device was prepared according to the following procedure.

The jacket of a multi-mode fiber (BFH37, High OH, from 1.5 mm to 0.6 mm, from Thorlabs) was stripped off with a razor. The hard polymer cladding was burned away with a torch flame. The core of the fiber was then cleaned in an ultrasonic bath with deionized water, acetone, isopropyl alcohol successively for 20 min, and dried in oven for 15 min at 100° C. The cleaned fiber was subsequently coated with indium-tin-oxide (In/Sn=90:10) by dip coating (over 10 layers). See Dip Coated ITO thin films through sol-gel process using metal salts, Sutapa Roy Ramanan, Thin Solid Films, 389 (2001), 207.

The ITO coated fiber was thoroughly cleaned in an ultrasonic bath with acetone and isopropyl alcohol successively for 20 min, and dried in oven at 100° C. The fiber was then exposed to ozone for 90 min (rotating the fiber 3 times every after 30 min). A PEDOT:PSS solution (Baytron P from Bayer) was subsequently deposited on the fiber by dip coating and dried at 100° C. for 15 min. (the thickness of PEDOT:PSS film was about 150 nm).

Subsequently, a solution of P3HT (American Dye):PCBM (American Dye)=1:0.8 in chlorobenzene was deposited on the fiber through dip coating. (the thickness of polymer film was about 300 nm). In the final step, an Al electrode was deposited via thermal evaporation at the pressure of 10⁻⁶ torn The Al electrode partially covered the photosensitive P3HT:PCBM organic layer covering about 50% of the photosensitive P3HT:PCBM organic layer. The thickness of Al electrode was about 100 nm. The length of the fiber was about 1 cm.

After preparation, the photovoltaic performance of the fiber optoelectronic device was characterized in terms of open circuit voltage and short circuit current by irradiating the side or circumferential area of the fiber optoelectronic device with radiation of having a bandpass of about 400 nm to about 800 nm and an intensity of 100 mW/cm².

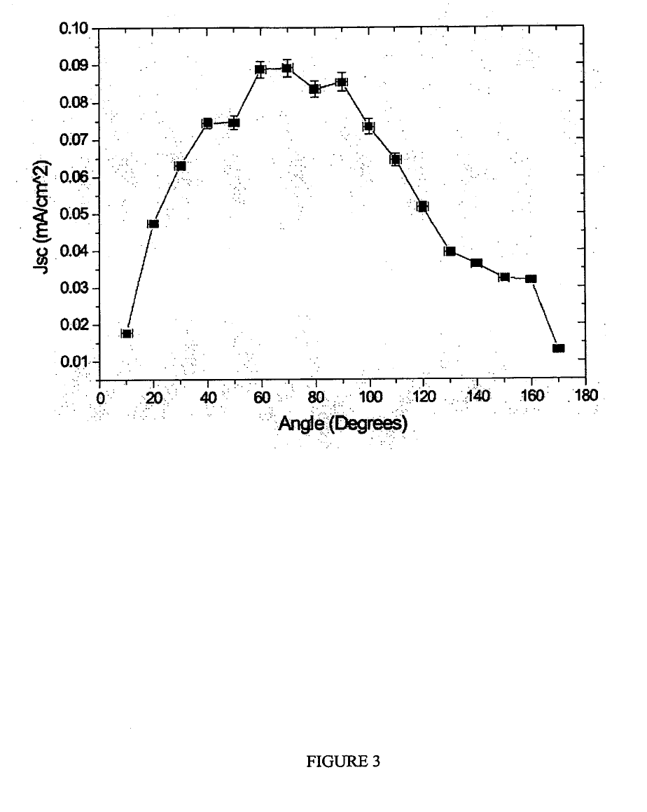

FIG. 3 illustrates short circuit currents for the prepared optoelectronic device as a function of the incident angle of the received radiation at a side of the fiber. As provided in FIG. 3, the short circuit current varies with the angle of incidence of the radiation received at a side of the fiber. As a result, the performance of the optoelectronic device can be varied as a function of the angle of the radiation incident at the side of the optoelectronic device.

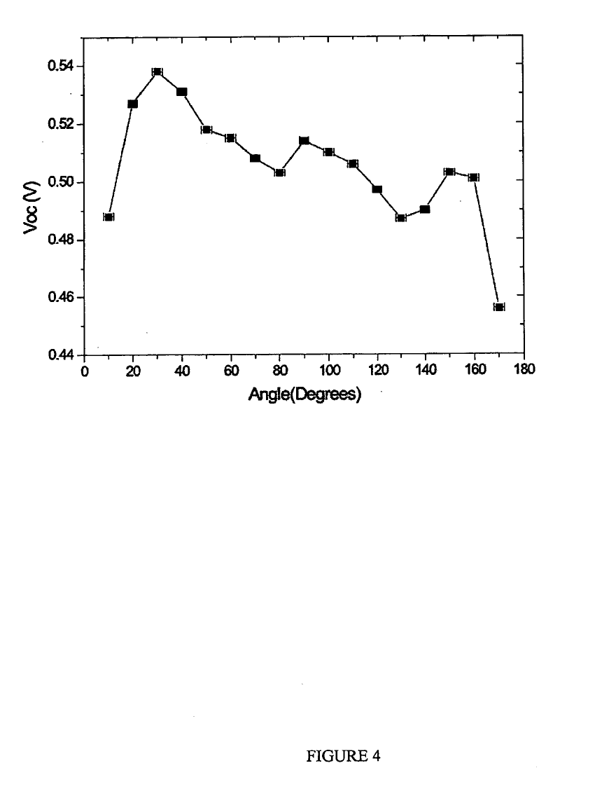

FIG. 4 illustrates open circuit voltages for the prepared optoelectronic device as a function of the incident angle of the received radiation at a side of the fiber. As illustrated in FIG. 4, the open circuit voltage varies with the angle of incidence of the radiation received at a side of the fiber. As a result, the performance of the optoelectronic device can be varied as a function of the angle of the radiation incident at the side of the optoelectronic device.

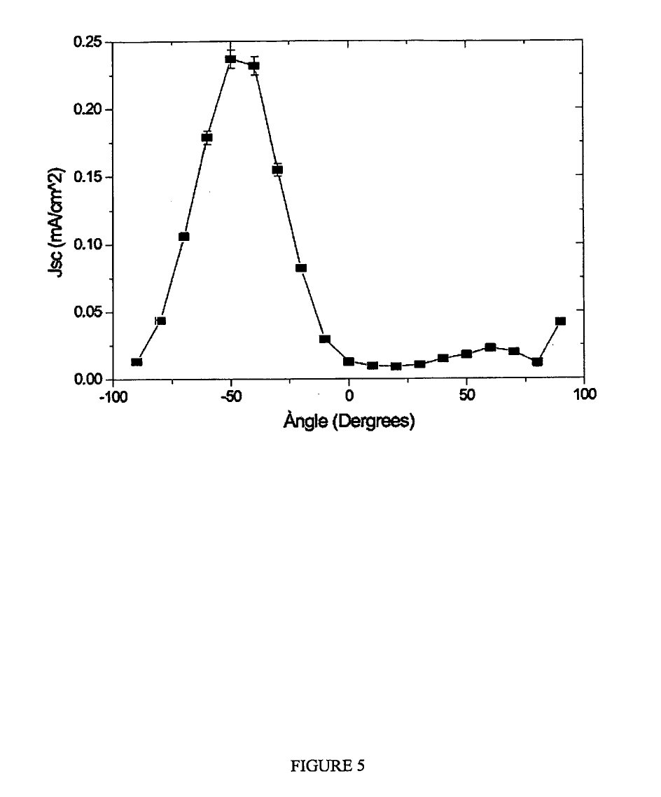

FIG. 5 illustrates short circuit currents for the prepared optoelectronic device as a function of the incident angle of the received radiation about the circumference of the fiber. As provided in FIG. 5, the short circuit current varies with the angle of incidence of the radiation received about the circumference of the fiber. As a result, the performance of the optoelectronic device can be varied as a function of the angle of the radiation incident around the circumference of the optoelectronic device.

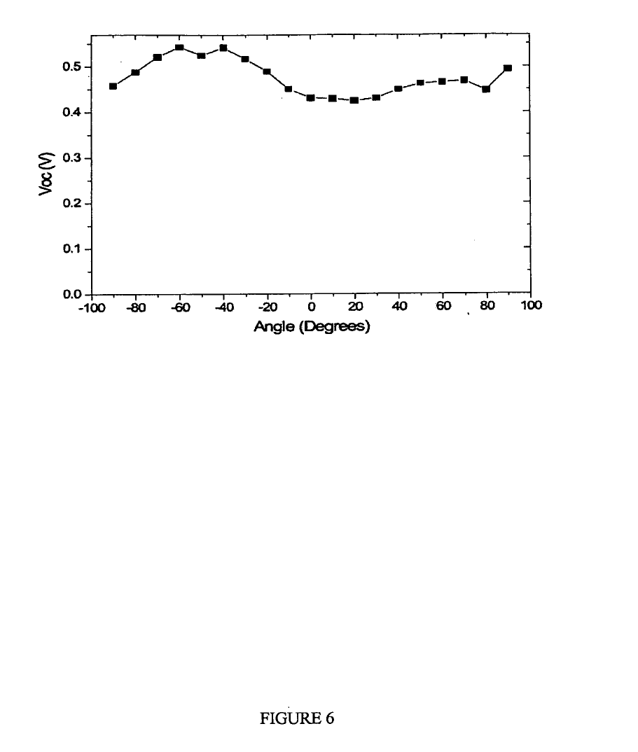

FIG. 6 illustrates open circuit voltages for the prepared optoelectronic device as a function of the incident angle of the received radiation about the circumference of the fiber. As illustrated in FIG. 6, the open circuit voltage varies with the angle of incidence of the radiation received around the circumference of the fiber. As a result, the performance of the optoelectronic device can be varied as a function of the angle of the radiation incident around the circumference of the optoelectronic device.

Various embodiments of the invention have been described in fulfillment of the various objects of the invention. It should be recognized that these embodiments are merely illustrative of the principles of the present invention. Numerous modifications and adaptations thereof will be readily apparent to those skilled in the art without departing from the spirit and scope of the invention.

That which is claimed is:

1. An apparatus comprising:
a fiber core;
a radiation transmissive first electrode surrounding the fiber core;
at least one photosensitive organic layer surrounding the first electrode and electrically connected to the first electrode; and
a non-radiation transmissive second electrode partially covering the organic layer and electrically connected to the organic layer.

2. The apparatus of claim 1, wherein the fiber core comprises an optical fiber.

3. The apparatus of claim 2, wherein the optical fiber comprises a glass optical fiber, quartz optical fiber, or a plastic optical fiber.

4. The apparatus of claim 1, wherein the radiation transmissive first electrode comprises a radiation transmissive conducting oxide.

5. The apparatus of claim 4, wherein the radiation transmissive conducting oxide comprises indium tin oxide, gallium indium tin oxide, or zinc indium tin oxide.

6. The apparatus of claim 1, wherein the photosensitive organic layer comprises a photoactive region.

7. The apparatus of claim 6, wherein the photoactive region comprises at least one bulk heterojunction between a donor material and an acceptor material.

8. The apparatus of claim 7, wherein the donor material comprises a polymeric phase and the acceptor material comprises nanoparticle phase.

9. The apparatus of claim 8, wherein the polymeric phase comprises a conjugated polymer.

10. The apparatus of claim 9, wherein the conjugated polymer comprises poly(3-hexylthiophene), poly(3-octylthiophene), or mixtures thereof.

11. The apparatus of claim 8 wherein the nanoparticle phase comprises fullerenes, carbon nanotubes, or mixtures thereof.

12. The apparatus of claim 1, wherein the non-radiation transmissive second electrode comprises a metal.

13. The apparatus of claim 1, wherein the non-radiation transmissive second electrode covers less than about 60% of the photosensitive organic layer.

14. The apparatus of claim 1, wherein the non-radiation transmissive second electrode covers less than about 50% of the photosensitive organic layer.

15. The apparatus of claim 1, wherein the non-radiation transmissive second electrode covers less than about 30% of the photosensitive organic layer.

16. The apparatus of claim 1, wherein the fiber core is bent at an angle.

17. The apparatus of claim 16, wherein the angle is about 90 degrees.

18. The apparatus of claim 16, wherein the angle is less than about 90 degrees.

19. The apparatus of claim 16, wherein the angle is greater than about 90 degrees.

20. The apparatus of claim 1, wherein the apparatus is a photovoltaic cell.

21. An apparatus comprising:
at least one pixel comprising at least one photovoltaic cell, the photovoltaic cell comprising:
a fiber core;
a radiation transmissive first electrode surrounding the fiber core;
at least one photosensitive organic layer surrounding the first electrode and electrically connected to the first electrode; and
a non-radiation transmissive second electrode partially covering the organic layer and electrically connected to the organic layer.

22. The apparatus of claim 21, wherein the fiber core comprises an optical fiber.

23. The apparatus of claim 22, wherein the optical fiber comprises a glass optical fiber, a quartz optical fiber, or a plastic optical fiber.

24. The apparatus of claim 21, wherein the at least one pixel comprises a plurality of photovoltaic cells.

25. The apparatus of claim 24, wherein the plurality of photovoltaic cells are bundled.

26. The apparatus of claim 21 comprising an array of pixels.

27. The apparatus of claim 21, wherein the apparatus is a solar collector.

28. The apparatus of claim 21, wherein the fiber core is bent at an angle.

29. The apparatus of claim 28, wherein the angle is about 90 degrees.

30. The apparatus of claim 28, wherein the angle is less than about 90 degrees.

31. The apparatus of claim 28, wherein the angle is greater than about 90 degrees.

32. The apparatus of claim 21, wherein the non-radiation transmissive second electrode covers less than about 60% of the photosensitive organic layer.

33. The apparatus of claim 21, wherein the non-radiation transmissive second electrode covers less than about 50% of the photosensitive organic layer.

34. The apparatus of claim 21, wherein the non-radiation transmissive second electrode covers less than about 30% of the photosensitive organic layer.

35. A method of making an optoelectronic device comprising:
providing a fiber core;
disposing a radiation transmissive first electrode on a surface of the core;
disposing at least one photosensitive organic layer in electrical communication with the first electrode; and
disposing a non-radiation transmissive second electrode in electrical communication with the organic layer, wherein the non-radiation transmissive second electrode partially covers the organic layer.

36. The method of claim 35, wherein the fiber core comprises an optical fiber.

37. The method of claim 36, wherein the optical fiber comprises a glass optical fiber, quartz optical fiber, or a plastic optical fiber.

38. The method of claim 35, wherein the radiation transmissive first electrode comprises a radiation transmissive conducting oxide.

39. The method of claim 35, wherein the photosensitive organic layer comprises a photoactive region.

40. The method of claim 39, wherein the photoactive region comprises at least one bulk heterojunction between a donor material and an acceptor material.

41. The method of claim 40, wherein the donor material comprises a polymeric phase and the acceptor material comprises nanoparticle phase.

42. The method of claim 35, wherein the non-radiation transmissive second electrode covers less than about 60% of the photosensitive organic layer.

43. The method of claim 35, wherein the non-radiation transmissive second electrode covers less than about 50% of the photosensitive organic layer.

44. The method of claim 35, wherein the non-radiation transmissive second electrode covers less than about 30% of the photosensitive organic layer.

45. The method of claim 35, wherein the fiber core is bent at an angle.

46. The method of claim 45, wherein the angle is about 90 degrees.

47. The method of claim 45, wherein the angle is less than about 90 degrees.

48. The method of claim 45, wherein the angle is greater than about 90 degrees.

49. A method of converting electromagnetic energy into electrical energy comprising:
receiving radiation at a side of an optical fiber core;
transmitting the radiation into at least one photosensitive organic layer;
generating excitons in the organic layer; and
separating the excitons into electrons and holes.

50. The method of claim 49, wherein the fiber core comprises an optical fiber.

51. The method of claim 50, wherein the optical fiber comprises a glass optical fiber, quartz optical fiber, or a plastic optical fiber.

52. The method of claim 49, wherein the photosensitive organic layer comprises a photoactive region.

53. The method of claim 52, wherein the photoactive region comprises at least one bulk heterojunction between a donor material and an acceptor material.

54. The method of claim 53, wherein the donor material comprises a polymeric phase and the acceptor material comprises nanoparticle phase.

55. The method of claim 49, wherein the fiber core is bent at an angle.

56. The method of claim 55, wherein the angle is about 90 degrees.

57. The method of claim 55 wherein the angle is less than about 90 degrees.

58. The method of claim 55, wherein the angle is greater than about 90 degrees.

59. The method of claim 49 further comprising removing the electrons into an external circuit.
